(19) United States
(12) Patent Application Publication
(10) Pub. No.: US 2005/0190807 A1
(43) Pub. Date: Sep. 1, 2005

(54) Semiconductor laser

(76) Inventor: Tomoichiro Toyama, Kyoto-shi (JP)

Correspondence Address: RABIN & Berdo, PC, 1101 14TH STREET, NW, SUITE 500, WASHINGTON, DC, 20005, US

(21) Appl. No.: 11/058,241

(22) Filed: Feb. 16, 2005

(30) Foreign Application Priority Data
Feb. 27, 2004 (JP) 2004-052997

(51) Int. Cl. H01S 5/00

(52) U.S. Cl. 372/49.01

(57) ABSTRACT

A semiconductor lamination part (9) is formed by laminating semiconductor layers on a semiconductor substrate (1) so as to emit laser light. A first dielectric film (17) is provided on one edge face of the semiconductor lamination part to have a low and desired reflection coefficient and a second dielectric film (18) is provided on another edge face. A thickness of the first dielectric film is set to give a desired reflection coefficient according to a variation curve of a reflection coefficient to a thickness of aluminum oxide film at a constant oscillating wavelength and to have a positive gradient in the curve, or to have a negative gradient in variation curve of a reflection coefficient to a wavelength, and further has a thickness of 0.6λ or more in the optical distance. As a consequence, a semiconductor laser for a high output is obtained, in which a COD level can become high and an output can be stabilized even if a wavelength changes with an increasing temperature by operating of the semiconductor laser.

### FIELD OF THE INVENTION

The present invention relates to a semiconductor laser especially suitable for use in a pick-up light source for a CD, a digital versatile disk (hereinafter, referred to as “DVD”), a DVD-ROM, a data writable CD-R/RW or the like. More particularly, the present invention relates to a semiconductor laser, in which a level of a catastrophically optical damage (hereinafter, referred to as “COD”) can be kept high even at a high output and also a lifetime can be prolonged.

### BACKGROUND OF THE INVENTION

For example, a semiconductor laser is configured in a structure as shown in FIG. 5. That is, on a semiconductor substrate 21, is laminated a semiconductor lamination part 22 in which semiconductor layers are laminated to form a stripe-shaped light emitting portion. And an edge face of a resonator is formed by cleaving a wafer into bars, on each edge face of which, are formed a first dielectric film 23 and a second dielectric film 24 with an adjusted reflection coefficient respectively. Thereafter, each of bars is divided into chips by dicing or the like.

In this configuration, the reflection coefficient of each edge face is set so as to get an oscillating output mainly from one edge face (front edge face) of the light emitting portion and a small part of the output for monitoring the oscillating output from another edge face (rear edge face). And finally the laser chip is bonded on a sub mount 25 made of semiconductor substrate made of Si or AlN or the like, and applied to a pick up.

In order to get a oscillating output mainly from the front edge face, as described above, the first dielectric film 23 formed on the front edge face has a low reflection coefficient and the second dielectric film 24 formed on the rear edge face has a high reflection coefficient. Actually each dielectric film is configured in various compositions, because a value of the reflection coefficient or a structure of the dielectric film (being composed of single or multi layers) depends upon a semiconductor laser which is planed to use. For example, at the front edge face, a combination of an aluminum oxide film of a thickness of 0.15λ and a silicon film of a thickness of 0.4λ in the optical distance, respectively, is used so as to make a reflection coefficient as small as 2% or smaller to make it easy to get a high output and prevent the decrease in a COD level by heat generated at the edge face, and at the rear edge face, for example, four layered films are laminated alternately with two aluminum oxide films of a thickness of 0.25λ in the optical distance and two silicon oxide films of the same thickness in order to get a high reflection coefficient as high as 92% (cf. Japan Patent Application Laid-Open No. 2003-86886).

In the semiconductor laser, as described above, dielectric films are formed on cleavage surfaces of a stripe-shaped light emitting portion and the reflection coefficients at the front edge face and the rear one are adjusted to have desired values at an oscillating wavelength. However, once the semiconductor laser begins to operate, an operating current is concentrated in the light emitting portion and a temperature of the portion rises. This increasing temperature induces a higher threshold current which leads to a decrease in a laser emitting efficiency and a longer oscillating wavelength which leads to an variation in the reflection coefficient. And, as a result, a problem of a variation of the laser output is raised.

Moreover, in a high output semiconductor laser, a first dielectric film is formed so as to make a reflection coefficient of an emitting edge face low and to make easy to get an oscillating output from a front edge face. On the other hand the reflection coefficient of the front edge face sometimes needs to be adjusted to a desired value, because the smaller reflection coefficient is not always the better, considering an effect by noises caused by returned beams. As a film is generally formed by a sputtering process or the like, the dielectric film is formed in a preferably small thickness which can give a desired reflection coefficient, considering process cost.

By the way, as for a high output semiconductor laser, for example, for CD-R/RW, as a maximum amplitude of an electric field lies in an interface between the cleavage surface of a semiconductor laser chip and the first dielectric film, therefore, by the decreasing in a COD level caused by the increasing in the temperature of the first dielectric film, a high output semiconductor laser with an output of 80 mW or more is especially liable to be broken in a short period, from 100 hours to 200 hours, on an accelerated life test at a high temperature (for example, 75° C.) with a high output (for example, 200 mW), even if the reflection coefficient is as small 8.5% or so.

### SUMMARY OF THE INVENTION

The present invention is directed to solve the above-described problem and an object of the invention is to provide a semiconductor laser in which an output level can be stabilized, even if an oscillation wavelength varies with an increasing temperature upon a laser operation, and also a COD level can be kept high, even if the COD level of an emitting side edge face (the front edge face) is liable to decrease in use of a high output.

The present inventor earnestly studied to solve a problem that a variation of an output level can not be controlled accurately according to an increasing temperature of a semiconductor laser by operating, and that a destruction of a semiconductor laser of a high output occurs in a short period of from 100 hours to 250 hours under an accelerated life testing at a high temperature (for example, 75° C.) with a high output level (for example, 200 mW).

As a result, it was found that in a case of a normally decided thickness so as to have a desired reflection coefficient, as the reflection coefficient is set in a region where the reflection coefficient increases with a wavelength at a constant thickness of the dielectric film, an output level decreases more because of a decreasing in an external quantum efficiency caused by an increasing operating wavelength, and as a dissipation of heat generated in the cleavage surface of a laser chip is not sufficient, the heat makes a semiconductor crystal melt at a cleavage surface and an edge face break down.

And consequently, it was found that a COD level can be kept high even if the semiconductor laser is operated with a high output level of 250 mW or more; by applying a thickness of the dielectric film which is provided in such manner that a variation of the reflection coefficient has a negative gradient to that of the oscillating wavelength in a desired value, the reflection coefficient is decreased by the increase in the oscillating wavelength, and the external quantum efficiency increases to lead to an increasing output and to cancel an influence of decrease in the output caused by the variation of the wavelength; and by applying an aluminum oxide film which has a high thermal conductivity and a thickness as possible as thick, for the dielectric film formed on the front edge face, a sufficient dissipation of the heat can be achieved.

A semiconductor laser according to the present invention includes; a semiconductor substrate, semiconductor lamination part in which semiconductor layers are laminated on the semiconductor substrate so as to form a stripe-shaped light emitting portion and emit a laser light of an oscillating wavelength λ, a first dielectric film formed on one edge face of the stripe-shaped light emitting portion, so as to have a predetermined reflection coefficient, and a second dielectric film formed on another edge face of the stripe-shaped light emitting portion, so as to have a high reflection coefficient which is higher than that of the first dielectric film, wherein the first dielectric film is made of aluminum oxide and has a thickness which is derived from a desired reflection coefficient and a positive gradient in a variation curve of a reflection coefficient to a thickness of an aluminum oxide film at the wavelength λ, and which is 0.6λ or more in an optical distance.

Here, the optical distance means an optical path length which is defined by nL, where n represents a refractive index of a medium and L represents a length of a light path in the medium.

A semiconductor laser according to the present invention in another aspect includes; a semiconductor substrate, a semiconductor lamination part in which semiconductor layers are laminated on the semiconductor substrate so as to form a stripe-shaped light emitting portion and emit a laser light of an oscillating wavelength λ, a first dielectric film formed on one edge face of the stripe-shaped light emitting portion, so as to have a predetermined reflection coefficient; and a second dielectric film formed on another edge face of the stripe-shaped light emitting portion, so as to have a high reflection coefficient which is higher than that of the first dielectric film; wherein the first dielectric film is made of aluminum oxide and has a thickness which is derived from a desired reflection coefficient and has a negative gradient in a curve of a variation of a reflection coefficient to a variation of an oscillating wave length, when an oscillating wavelength is the λ, and which is 0.6λ or more in an optical distance.

It is preferable in order to stabilize an output for a variation in an oscillating wavelength caused by a semiconductor laser operating that the first dielectric film is provided in a thickness so as to satisfy the inequality:
−1≦(dRf/dλ)<0,
where the dRf/dλ represents a gradient of reflection coefficient of the curve of the reflection coefficient.

It is also preferable to get a sufficient dissipation of heat at a stripe-shaped emitting portion and suppress a variation of reflection coefficient caused by fluctuation in production process, that the thickness of the first dielectric film is from 0.6λ to 1.5λ in the optical distance.

According to the present invention, a problem in which the edge face is broken by an excess heating can be prevented, because the heat generated in the edge face of the stripe-shaped light emitting portion is dissipated across the dielectric film efficiently, as the dielectric film is formed in a thickness giving a desired reflection coefficient and also formed 0.6λ thick or more.

In other words, as for an edge face of an output side of the light emitting portion of a semiconductor laser produced by a prior art, single layered dielectric film or mulch layered dielectric film has been formed simply so as to give a desired reflection coefficient. In contrast, according to the present invention, as the edge face of an output side (front edge face) is formed not only by adjusting its reflection coefficient to a desired value, but also using a single layer of aluminum oxide alone which has a higher thermal conductivity than a semiconductor lamination part and also having a thickness of 0.6λ or more in the optical distance, the dissipation of the heat can be obtained across the larger area. As a result, an increasing of the temperature of the edge face of the light emitting portion can be suppressed and the COD level can be kept high, thereby the semiconductor laser of the very long lifetime can be obtained, such as 500 hours or more at a high temperature aging (75° C.) with a high output (200 mW).

Moreover, according to the present invention, not only a thickness of the first dielectric film is adjusted so as to have a desired reflection coefficient, but also it is adjusted so as to have a positive variation rate of a reflection coefficient to a thickness of the dielectric film at a constant wavelength, or so as to have a negative variation rate of a reflection coefficient to a wavelength at a constant thickness of the dielectric film. Therefore, although an oscillating wavelength has characteristics to become longer with beginning of a laser operation, a reflection coefficient decreases just to a slight increasing in a wavelength, as for the same thickness of the dielectric film. Consequently, an increasing tendency of an output of a laser light emitted outside, as described above, cancels a decreasing tendency in an output caused by the increasing threshold current, and an external quantum efficiency is raised, therefore the semiconductor laser can operate without decreasing in the output emitted outside, even if a temperature of the laser chip rise.

Moreover, since the semiconductor laser for high output in which the reflection coefficient of the first dielectric film (a front edge face) is adjusted to a low value of about several percent, by adjusting the reflection coefficient not only to a desired value, but also a positive gradient of the reflection coefficient to a thickness of the dielectric film, a variation of the reflection coefficient can be suppressed, because the reflection coefficient of the dielectric film to a thickness of the dielectric film varies to a relative minimum side when an oscillating wavelength shifts to a longer one. In other words, in case that a desired reflection coefficient is low and located near a relative minimum in a reflection coefficient curve to an oscillating wavelength, a variation can be suppressed even if the wavelength shifts to longer, because a variation is small in the side of the relative minimum, although that is large in the opposite side to the relative minimum side.

### BRIEF DESCRIPTION OF THE DRAWINGS

FIG. 1A and FIG. 1B are a perspective and a cross-sectional explanatory view showing a semiconductor laser in one embodiment according to the present invention;

FIG. 2 is a graph illustrating variation in a reflection coefficient at an edge face to a thickness of a dielectric film at a constant wavelength;

FIG. 3 is a graph illustrating variation in a reflection coefficient at an edge face to a wavelength at a constant thickness of a dielectric film;

FIG. 4 is a graph illustrating variation in a COD characteristics to a thickness of a dielectric film; and

FIG. 5 is a view showing a structure in which a semiconductor laser is mounted on a sub-mount.

### DETAILED DESCRIPTION

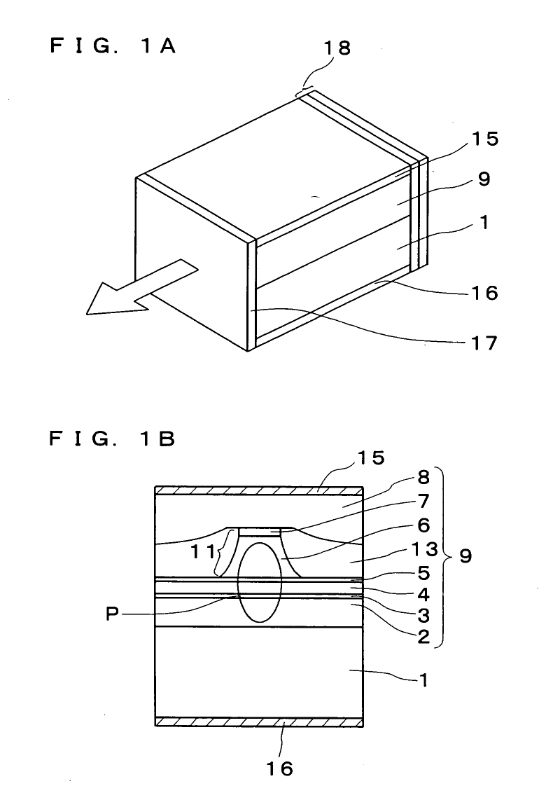

A description will be given below of a semiconductor laser according to the present invention in reference to the drawings. As shown in FIG. 1A illustrating a cross-sectional explanatory view of a semiconductor laser in one embodiment, in a semiconductor laser according to the present invention a semiconductor lamination part 9 is provided on a semiconductor substrate 1, in which semiconductor layers are laminated to form a stripe-shaped light emitting portion and emits a laser of wavelength λ. And, on one edge face of a stripe-shaped light emitting portion (cf. a beam spot P in FIG. 1B) of the semiconductor lamination part 9, a first dielectric film 17 is formed so as to have a low and desired reflection coefficient. In contrast, on another edge face of the light emitting portion, a second dielectric film 18 is formed so as to raise a reflection coefficient and have a high one. In the semiconductor laser according to the present invention, the first dielectric film 17 is made of aluminum oxide and has a thickness which is derived from a desired reflection coefficient and a positive gradient in a variation curve of a reflection coefficient to a thickness of an aluminum oxide film at the wavelength λ, and which is 0.6λ or more, preferably 0.7λ or more and still preferably 0.8λ or more in the optical distance.

The present inventor studied earnestly to solve the problems described above an output level decreases with a variation of reflection coefficient in accordance with a wavelength shift to longer by operating of the semiconductor laser, and that in case of a high output semiconductor laser, the semiconductor laser is especially liable to break in a short period of an accelerated life test.

Consequently, the present inventor has found two facts as follows; that a decreasing in an output caused by a variation of a wavelength can be prevented by applying a thickness of a dielectric film giving a desired reflection coefficient and a negative gradient in a variation of a reflection coefficient to a wavelength, because this application leads to an increase in an external quantum efficiency by decreasing in a variation of a reflection coefficient with a wavelength and making small the reflection coefficient itself when the wavelength increasing, although in the prior art, the variation and value of the reflection coefficient increases to make the output lower when the wavelength increasing; and that the breakage caused by a COD can be also prevented by application of the first dielectric film 17 thicker than usual and made of aluminum oxide, of a high thermal conductivity, leading to a sufficient dissipation of the heat, although in the prior art, a semiconductor crystal on the edge face is melt to destroy the edge face, because a heat generated on the edge face is not dispersed.

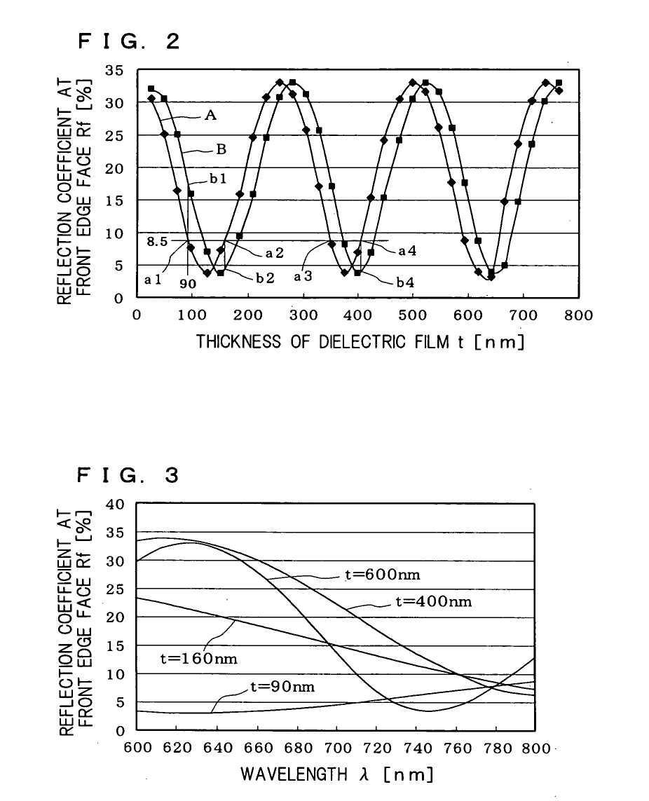

In a case where a first dielectric film 17 is a single layer structure made of aluminum oxide (Al₂O₃) and the wavelength is 780 nm (A) and 790 nm (B), a variation of a reflection coefficient Rf to a thickness of the dielectric film is shown in FIG. 2. The graph in FIG. 2 shows that the reflection coefficient changes periodically in accordance with the variation of the thickness t of the first dielectric film 17 formed on the edge face of the light emitting portion, when the thickness of the film changes variously. In the prior art, as the first dielectric film 17 is formed by sputtering process which takes a long time, for example 3 minutes or so to get a thickness of 10 nm, the first dielectric film is formed in a thickness of about 90 nm that gives a desired reflection coefficient, for example 8.5% at 780 nm.

However, in a case of the longer wavelength as 790 nm, as the curve of the reflection coefficient to the thickness of the dielectric film is got by shifting a curve of a shorter wavelength to the right in parallel as shown by curve B in FIG. 2, the thickness of the dielectric film should be set thicker to get the same reflection coefficient. In the contrast, in a case of wavelength 780 nm where the thickness of the first dielectric film 17 is set so as to get a desired reflection coefficient, when an oscillating wavelength changes longer, the reflection coefficient becomes higher than that of an initial setting because the thickness of the dielectric film does not change (the point of b1 in FIG. 2). Therefore, an emitted output decreases by decrease in an external quantum efficiency.

Then, the present inventor has resolved this problem by applying a thickness of the dielectric film in which the variation of reflection coefficient becomes smaller when the wavelength shifts to longer, as well as setting the thickness of the dielectric film so as to give a desired reflection coefficient. Especially, as for a high output semiconductor laser, the reflection coefficient of the front edge face is set to a low value in order to get an output mainly from the front edge face, therefore, the reflection coefficient on the front edge face is normally set to a point near a relative minimum point in a curve which expresses a variation of a reflection coefficient to a thickness of the dielectric film as shown in the FIG. 2. Therefore, when the thickness of the dielectric film is changed toward the relative minimum point in the curve, the variation of the reflection coefficient becomes small, but it is changed toward the opposite side, the variation of the reflection coefficient becomes large.

In the contrast, a curve of the reflection coefficient of same kind in a case of a longer wavelength, as shown in B of FIG. 2, shifts to parallel by a width of some larger thickness of the dielectric film. Therefore, among the points (shown by a1, a2, a3, a4 in FIG. 2) of the same value of the reflection coefficient at a wavelength 780 nm for example, by applying points (shown by a2, a4 in FIG. 2) around which the gradient of the reflection coefficient is positive (dRf/dλ>0), the reflection coefficient in the light having a longer wavelength and the same thickness of the dielectric film shifts to the relative minimum side (shown by b2, b4 in FIG. 2). It leads to a small variation of the reflection coefficient. Thereby, as the wavelength shifts longer by the operating temperature, the reflection coefficient Rf itself shifts smaller and the external quantum efficiency increases. As a result, a decrease in an oscillating output caused by an increase in threshold current by increasing temperature can be compensated.

In the discussion described above, a measure to cope with a variation of the oscillating wavelength of the semiconductor laser was examined by setting a thickness of the dielectric film so as to suppress a change of the reflection coefficient according to a variation of the reflection coefficient to the thickness of the dielectric film. On the other hand, as mentioned above, an output decreases by the rising threshold current with the increase of temperature caused by the semiconductor laser operating. Thereby, when a wavelength varies longer by an increasing temperature, a variation of the output caused by an increasing temperature can be prevented by setting a thickness of the dielectric film so as to decrease the reflection coefficient Rf.

For example, when the wavelength is varied at a constant thickness of the dielectric film giving a desired reflection coefficient Rf, the reflection coefficient varies periodically by the variation of wavelength λ, as shown in FIG. 3. Then, among the thicknesses which give a desired reflection coefficient, by applying the thickness which has a negative gradient (dRf/dλ) at around the oscillating wavelength 780 nm, a variation of an output caused by increasing temperature can be canceled.

In addition, when a value of the gradient (dRf/dλ) of the reflection coefficient to the wavelength λ is too large even if the gradient is negative, as the variation of the reflection coefficient itself becomes too large, a preferable condition is satisfying an inequality: −1<(dRf/dλ)<0. Under satisfying these conditions, by setting the thickness of the dielectric film according to FIG. 2 so as to get the desired reflection coefficient, the variation of the output caused by increase in temperature with semiconductor laser operation can be prevented.

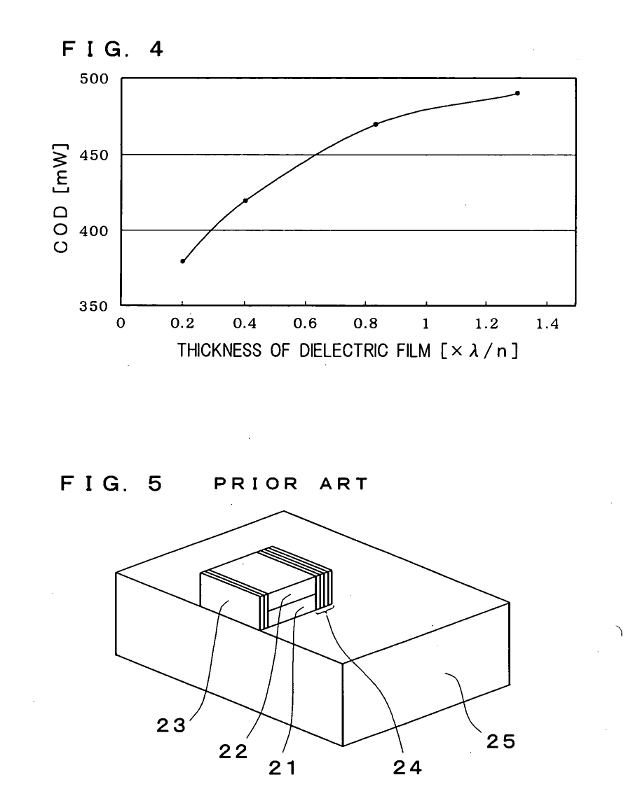

And as described above, by setting a thickness of the dielectric film to a certain thickness or more, the dissipation of the heat can be improved, a COD level can be kept very high and even the semiconductor laser of high output has never been broken in an aging period of 500 hours or more at a high temperature (75° C.) with a high output (200 mW). As a feature of a variation of COD characteristics is shown in FIG. 4, where aluminum oxide of a high thermal conductivity is applied for the first dielectric film and its thickness is varied, sufficient dissipation of heat can be obtained by applying the thickness of the dielectric film of 0.6λ or more (for the wavelength of 780 nm and a refractory index of aluminum oxide (n) of 1.62, the thickness of the dielectric film is physically 240 nm or more), preferably 0.7λ or more, and more preferably 0.8λ or more in the optical distance. As a result, none of thirty tested samples each of which is the semiconductor lasers for a high output of 250 mW or more, having the dielectric film of a thickness of 0.6λ or more, has not been broken in the 500 hours under an accelerated aging, described above.

From the viewpoint of heat dissipation, the thicker dielectric film is the more preferable, but, as an excessive thickness takes long time to form, leads a high cost and has a difficulty in control of the reflection coefficient of the dielectric film, the thickness of 1.5λ or less in the optical distance is actually preferable. In the concrete, when the thickness of the dielectric film was set in 0.8λ in the optical distance (the physical thickness of an aluminum oxide film is 400 nm=0.83λ/n) to get the reflection coefficient of 8.5%, an influence to a variation of the output caused by increasing temperature was decreased and a very long lifetime was achieved.

A second dielectric film 18 on a rear edge face is configured in a structure which has two couples of layers or so of an α-Si (amorphous silicon) film and an Al₂O₃ (aluminum oxide) film of the same thickness λ/(4 n) (λ is an oscillating wavelength and n is refractive index of the dielectric film) so as to have a reflection coefficient Rr of for example 80˜95%, to get a large output from the front edge face by oscillating in a resonator by reflecting most of light. But at this rear edge face, as it is sufficient to get a desired Rr, the material and the composition of the film does not matter.

Although, a semiconductor substrate 1, a semiconductor lamination part 9 and a contact layer 15, 16 have the same configurations as those of the prior art. That is, for example, for a semiconductor lamination part 9, an AlGaAs based compound semiconductor for the infrared beam 780 nm or an InGaAlP based compound semiconductor for the red beam of 650 nm is used; and for a semiconductor substrate 1, on which these semiconductor materials are laminated, although an GaAs substrate is normally used, other compound semiconductor materials can be accepted. A conductivity type of the semiconductor substrate 1 depends upon an application set in which the semiconductor laser is assembled and in accordance with n-type or p-type expected to the semiconductor substrate 1, the type of the semiconductor lamination part 9 is decided consequently. In the following concrete sample, the explanation will be done in the case that the semiconductor substrate is n-type.

In the example shown in FIG. 1A and FIG. 1B, the semiconductor lamination part 9 includes the n-type clad layer 2, the non-doped, n-type or p-type active layer 3, the p-type first clad layer 4, a p-type etching stop layer 5, the p-type second clad layer 6, a cap layer 7, an n-type current block layer 13 embedded on both sides of the p-type second clad layer 6 etched in a ridge manner, and a p-type contact layer 8 formed on the cap layer 7 and the current block layer 13.

Specifically, the n-type GaAs substrate 1 is put into, for example, a metal-organic chemical vapor deposition (abbreviated as “MOCVD”) apparatus, and then, a necessary material such as triethyl gallium (TEG), trimethyl aluminum (TMA), trimethyl indium (TMIn), phosphine (PH₃) or arsine (AsH₃) serving as reaction gas, SiH₄ as n-type dopant gas, or dimethyl zinc (DMZn) or cyclopentadienyl beryllium (Be(MeCp)₂) as p-type dopant gas according to the conductivity type of the semiconductor layer are introduced together with hydrogen (H₂) serving as carrier gas and the semiconductor layers are laminated by epitaxially growing each of the semiconductor layers at temperatures from about 500° C. to about 700° C., thus the semiconductor lamination part 9 is obtained.

The n-type clad layer 2 is made of, for example, Alₓ₁Ga₁₋ₓ₁As (0.3≦x1≦0.7: for example, x1=0.5), and is formed in about 2 μm to about 4 μm. The active layer 3 has a bulk structure made of Al_{y1}Ga_{1-y1}As (0.05≦y1≦0.2: for example, y1=0.15) or a single or multiple quantum well (an SQW or an MQW) structure including a well layer made of Al_{y2}Ga_{1-y2}As (0.01≦y2≦0.1: for example, y2=0.05) and a barrier layer made of Al_{y3}Ga_{1-y3}As (0.2≦y3≦0.5 and y2≦y3: for example, y3=0.3), and thus, is formed in about 0.01 μm to about 0.2 μm as a whole. The p-type first clad layer 4 is made of, for example, Alₓ₂Ga₁₋ₓ₂As (0.3≦x2≦0.7: for example, x2=0.5), and is formed in about 0.1 μm to about 0.5 μm. Another semiconductor layer may be interposed between any of the layers: for example, optical guide layers may be interposed between the active layer 3 and the clad layers 2 and 4, respectively.

Furthermore, the p-type or undoped etching stop layer 5 made of, for example, In_{0.49}Ga_{0.51}P is formed on the p-type first clad layer 4 in about 0.01 μm to about 0.05 μm. The p-type second clad layer 6 made of, for example, Alₓ₃Ga₁₋ₓ₃As (0.3≦x3≦0.7: for example, x3=0.5) is formed in about 0.5 μm to about 3 μm. The p-type In_{0.49}Ga_{0.51}P cap layer 7 is formed on the p-type second clad layer 6 in about 0.01 μm to about 0.05 μm. A ridge 11 is formed by etching both sides of the cap layer 7 and the p-type second clad layer 6. The current block layer 13 made of Al_{z}Ga_{1-z}As (0.5≦z≦0.8: for example, z=0.6) is formed on both sides of the ridge 11 in such a manner as to embed the sides of the ridge 11.

Incidentally, the material of the etching stop layer 5 is not limited to In_{0.49}Ga_{0.51}P, but it may be, for example, In_{0.49}(Ga_{0.8}Al_{0.2})_{0.51}P and the like; and the cap layer 7 is adapted to prevent any formation of an oxide film on a semiconductor lamination part 9 so as to prevent any contamination when the contact layer is grown in a post-process, and therefore, other semiconductor layers, (for example, GaAs) may be used; and otherwise, no cap layer may be formed from the beginning as long as only contamination at the surface can be prevented by removing contamination by thermal cleaning. Moreover, etching for forming the ridge 11 is performed as follows; a mask made of SiO₂ or SiNₓ is formed by, for example, a CVD method; the cap layer 7 is selectively etched by, for example, dry etching; and subsequently, the p-type second clad layer 6 is etched with an etchant such as HCl, thereby forming the ridge 11 in a stripe-shaped-like manner (in a direction perpendicular to the sheet), as shown in FIG. 1B. Here, the exposed etching stop layer 5 may be removed.

The contact layer 8 is formed on a cap layer 7 and a current block layer 13, with the p-type GaAs layer of 0.05˜10 μm thick. On the contact layer 8 is formed a p-side electrode 15 made of Ti/Au or the like; and an n-side electrode 16 made of Au/Ge/Ni or Ti/Au is formed at the reverse surface of the semiconductor substrate 1 after the semiconductor substrate 1 is thinned by grinding, as described above. After this formation of the electrodes, chips are formed from a wafer by the cleavage and so on.

Although, the example described above is a case of AlGaAs based compound semiconductor, the InGaAlP based compound can be constituted in the same manner as in the example except that In_{0.49}(Ga₁₋ᵤAlᵤ)_{0.51}P (where 0.45≦u≦0.8: for example u=0.7) is used as the n-type and p-type clad layers; for example, the multiple quantum well (MQW) structure made of In_{0.49}(Ga₁₋ᵥ₁Alᵥ₁)_{0.51}P (where 0≦v1≦0.25: for example v1=0)/In_{0.49}(Ga₁₋ᵥ₂Alᵥ₂)_{0.51}P (where 0.3≦v2≦0.7: for example v2=0.4) is used as the active layer; and InAlP or GaAs is used as the current block layer.

Although the semiconductor laser having the ridge structure has been described in the examples, it is to be understood that the same should go for semiconductor lasers having other structures such as an SAS structure in which a current block layer is laminated between clad layers to form a current injection region, and then, the resultant stripe-shaped groove is removed by etching.

According to the present invention, described above, at the front edge face of the stripe-shaped light emitting portion, the dielectric film is formed not only so as to obtain the desired reflection coefficient, but also so as to dissipate the heat sufficiently to keep a COD level high by taking a certain thickness of the film or more, and so as to suppress the variation of the output with the variation of the oscillating wavelength caused by a laser operation. As a result, the semiconductor laser of very long lifetime and stable output can be obtained.

The semiconductor laser according to the present invention can be used as a pick-up light source for a CD, a DVD, a DVD-ROM, a data writable CD-R/RW or the like, and thus, it can be used for electric equipment such as a personal computer.

Although preferred examples have been described in some detail it is to be understood that certain changes can be made by those skilled in the art without departing from the spirit and scope of the invention as defined by the appended claims.

1. A semiconductor laser comprising:
a semiconductor substrate;
a semiconductor lamination part in which semiconductor layers are laminated on the semiconductor substrate so as to form a stripe-shaped light emitting portion and emit a laser light of an oscillating wavelength λ;
a first dielectric film formed on one edge face of the stripe-shaped light emitting portion, so as to have a predetermined reflection coefficient; and
a second dielectric film formed on another edge face of the stripe-shaped light emitting portion, so as to have a high reflection coefficient which is higher than that of the first dielectric film;
wherein the first dielectric film is made of aluminum oxide and has a thickness which is derived from a desired reflection coefficient and a positive gradient in a variation curve of a reflection coefficient to a thickness of an aluminum oxide film at the wavelength λ, and which is 0.6λ or more in an optical distance.

2. The semiconductor laser according to claim 1, wherein the thickness of the first dielectric film is from 0.6λ to 1.5λ in the optical distance.

3. The semiconductor laser according to claim 1, wherein the thickness of the first dielectric film is 0.7λ or more in the optical distance.

4. The semiconductor laser according to claim 1, wherein the thickness of the first dielectric film is 0.8λ or more in the optical distance.

5. The semiconductor laser according to claim 1, wherein the second dielectric film is configured in an alternate lamination with a film of a thickness of λ/4 made of an amorphous silicon and a film of a thickness of λ/4 made of aluminum oxide.

6. The semiconductor laser according to claim 1, wherein the semiconductor lamination part is formed of an AlGaAs based compound semiconductor or an InGaAlP based compound semiconductor.

7. The semiconductor laser according to claim 1, wherein the stripe-shaped light emitting portion in the semiconductor lamination part is configured in a ridge structure.

8. A semiconductor laser comprising:
a semiconductor substrate;
a semiconductor lamination part in which semiconductor layers are laminated on the semiconductor substrate so as to form a stripe-shaped light emitting portion and emit a laser light of an oscillating wavelength λ;
a first dielectric film formed on one edge face of the stripe-shaped light emitting portion, so as to have a predetermined reflection coefficient; and
a second dielectric film formed on another edge face of the stripe-shaped light emitting portion, so as to have a high reflection coefficient which is higher than that of the first dielectric film;
wherein the first dielectric film is made of aluminum oxide and has a thickness which is derived from a desired reflection coefficient and has a negative gradient in a curve of a variation of a reflection coefficient to a variation of an oscillating wave length, when an oscillating wavelength is the λ, and which is 0.6λ or more in an optical distance.

9. The semiconductor laser according to claim 8, wherein the first dielectric film is provided in a thickness so as to satisfy the inequality:
−1≦(dRf/dλ)<0,
where the dRf/dλ represents a gradient of reflection coefficient in the curve of the reflection coefficient.

10. The semiconductor laser according to claim 8, wherein the thickness of the first dielectric film is from 0.6λ to 1.5λ in the optical distance.

11. The semiconductor laser according to claim 8, wherein the thickness of the first dielectric film is 0.7λ or more in the optical distance.

12. The semiconductor laser according to claim 8, wherein the thickness of the first dielectric film is 0.8λ or more in the optical distance.

13. The semiconductor laser according to claim 8, wherein the second dielectric film is configured in an alternate lamination with a film of a thickness of λ/4 made of an amorphous silicon and a film of a thickness of λ/4 made of aluminum oxide.

14. The semiconductor laser according to claim 8, wherein the semiconductor lamination part is formed of an AlGaAs based compound semiconductor or an InGaAlP based compound semiconductor.

15. The semiconductor laser according to claim 8, wherein the stripe-shaped light emitting portion in the semiconductor lamination part is configured in a ridge structure.
